(19) United States
(12) Patent Application Publication
(10) Pub. No.: US 2016/0069354 A1
(43) Pub. Date: Mar. 10, 2016

(54) FAN CONTROL SYSTEM AND METHOD

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: TONG-QI HUANG, Wuhan (CN); JIAN-HUNG HUNG, New Taipei (TW)

(21) Appl. No.: 14/587,748

(22) Filed: Dec. 31, 2014

(30) Foreign Application Priority Data
Sep. 9, 2014 (CN) 201410454525.2

(51) Int. Cl. F04D 27/00; G05B 15/02; H05K 7/20

(52) U.S. Cl. CPC F04D 27/004; H05K 7/20209; G05B 15/02

(57) ABSTRACT

A fan control system and method is configured to adjust the speed of a fan. When the fan is employed to dissipate heat generated by a computer, a temperature sensor is used to output temperature regarding a computer, and the system then adjusts the speed of the fan according to the temperature automatically. When the fan is used to cool a user, an input value is input by a user. The system then adjusts the speed of the fan according to an input value, and the speed of the fan can be adjusted manually in this situation.

### FIELD

The subject matter herein relates to a fan control system and method.

### BACKGROUND

A universal system bus (USB) fan can be employed to dissipate heat generated by a computer.

### BRIEF DESCRIPTION OF THE DRAWINGS

Implementations of the present technology will now be described, by way of example only, with reference to the attached figures.

FIG. 1 is a block diagram of a fan control system of the present disclosure.

FIG. 2 is a flow chart of a fan control method of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently coupled or releasably coupled. The term “comprising,” when utilized, means “including, but not necessarily limited to”; it specifically indicates open-ended inclusion or membership in the so-described combination, group, series and the like.

The present disclosure is described in relation to a controllable system of a fan which rotation speed can be operated automatically or manually.

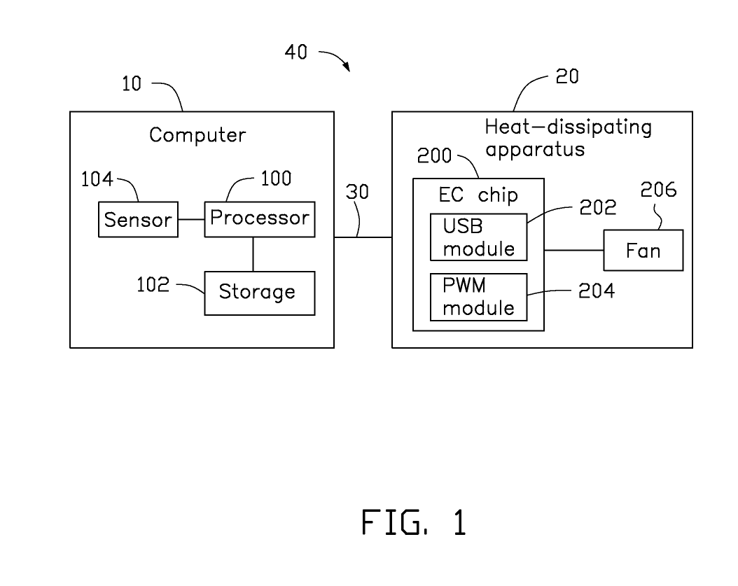

FIG. 1 illustrates a fan control system 40 of the present disclosure. The fan control system can comprise a computer 10, a universal serial bus (USB) cable 30, and a heat-dissipating apparatus 20 coupled to the computer 10 through the USB cable 30.

In one embodiment, the computer 10 can comprise a sensor 104, a storage 102, and a processor 100 coupled to the sensor 104 and the storage 102.

In one embodiment, the sensor 104 can be a temperature sensor. The sensor 104 can be placed within the computer 10, and output a temperature regarding the computer 10.

The storage 102 can store a plurality of programs to be executed by the processor 100, to perform certain functions.

The processor 100 can predefine operating modes of the system 40, such as an automatic mode, and/or a manual mode. The processor 100 can output a fan speed controlling signal with respect to the operating modes of the system 40.

In one embodiment, when the system 40 is operating in the automatic mode, the processor 100 can output the fan speed controlling signal with respect to the temperature output by the sensor 104. For example, the system 40 can be in the automatic mode as the heat-dissipating apparatus 20 is configured to dissipate heat generated by the computer 10. When the system 40 is operating in the manual mode, the processor 100 can output the fan speed controlling signal with respect to an input value from a user. For example, when the heat-dissipating apparatus 20 is configured to cool a user, the system 40 can be operated in the manual mode, and receives the input value from the user.

The processor 100 can output a control command with respect to the fan speed controlling signal via the USB cable 30.

In one embodiment, the heat-dissipating apparatus 20 can comprise an embedded controller (EC) chip 200, and a fan 206.

In one embodiment, the EC chip 200 can comprise a USB module 202 and a pulse width module modulation (PWM) module 204.

The USB module 202 can receive the control command from the processor 100 through the USB cable 30. The USB module 202 can perform parsing operation on the control command, to generate a speed instruction.

The PWM module 204 can receive the speed instruction from the USB module 202, and generate a PWM signal. The PWM signal can be transmitted to the fan 206 by the PWM module 204, and the fan 204 can adjust its rotation speed according to the PWM signal.

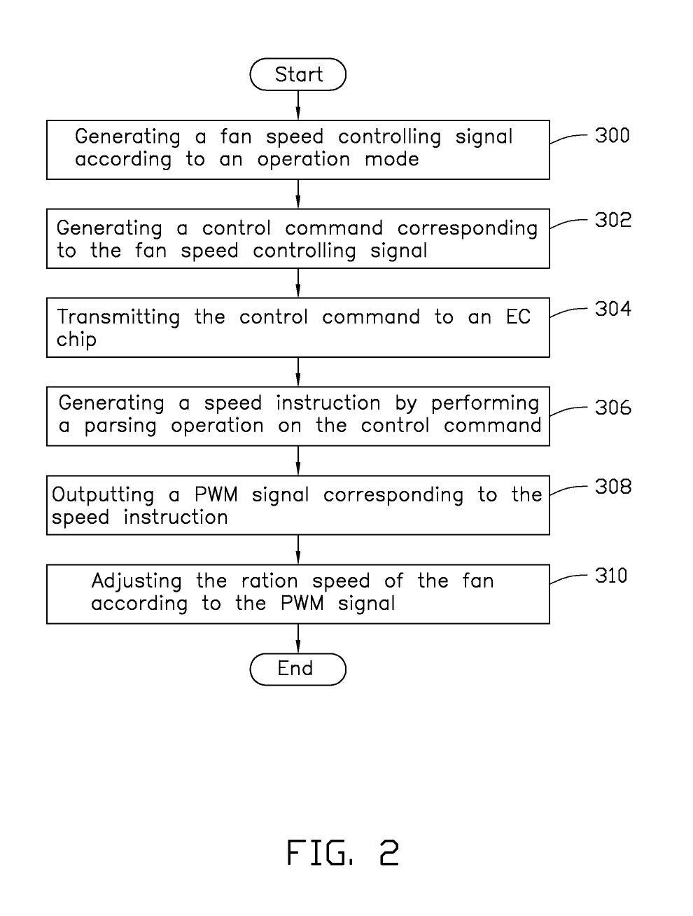

FIG. 2 illustrates a fan control method of the present disclosure. The illustrated order of blocks is illustrative only and the order of the blocks can change according to the present disclosure. Additional blocks can be added or fewer blocks may be utilized, without departing from this disclosure. The example method can begin at block 300.

At block 300, the processor 100 can predefine an operating mode, and output a fan speed controlling signal according to the operating mode. In one embodiment, the processor 100 can predefine an automatic mode and a manual mode.

At block 302, the processor 100 can generate a control command corresponding to the fan speed controlling signal.

At block 304, the processor 100 can output the control command to an EC chip 200.

At block 306, the EC chip 202 can receive the control command from the processor 100. The EC chip 202 can perform a parsing operation on the control command to generate a speed instruction.

At block 308, the EC chip 202 can generate a PWM signal corresponding to the speed instruction.

At block 310, the fan 206 can adjust its rotation speed according to the PWM signal.

While the disclosure has been described by way of example and in terms of the embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A fan control system comprising:
a processor;
a storage module storing a plurality of programs to be executed by the processor to perform functions comprising:
predefining an operating mode;
generating a fan speed controlling signal corresponding to the operating mode; and
outputting a control command regarding the fan speed controlling signal; and
a heat-dissipating apparatus, comprising:
a fan; and
an embedded control (EC) chip receiving the control command through a universal system bus (USB) cable;
wherein the EC chip performs a parsing operation on the control command to generate a speed instruction, the EC chip generates a pulse width modulation (PWM) signal to the fan, and the fan adjusts its rotation speed according to the PWM signal.

2. The fan control system of claim 1, further comprising:
a temperature sensor placed within a computer, generating a temperature regarding the computer;
wherein the operating modes comprise an automatic mode, and the processor generates the fan speed controlling signal according to the temperature from the temperature sensor, in response to the automatic mode.

3. The fan control system of claim 2, wherein the operation modes further comprises a manual mode, and the processor outputs the fan speed controlling signal according to an input value from a user, in response to the manual mode.

4. The fan control system of claim 2, wherein the EC chip comprises:
a USB module receiving the control command through the USB cable, and generating the speed instruction by performing the parsing operation on the control command; and
a PWM module generating the PWM signal according to the speed instruction from the USB mode.

5. The fan control system of claim 4, wherein the processor and the storage module are placed within the computer.

6. The fan control system of claim 3, wherein the EC chip comprises:
a USB module receiving the control command through the USB cable, and generating the speed instruction by performing the parsing operation on the control command; and
a PWM module generating the PWM signal according to the speed instruction from the USB mode.

7. The fan control system of claim 6, wherein the processor and the storage module are placed within the computer.

8. A fan control method comprising:
predefining an operating mode by a processor;
generating a fan speed controlling signal corresponding to the operating mode by the processor;
outputting a control command regarding the fan speed controlling signal by the processor;
receiving the control command by an embedded control (EC) chip;
performing a parsing operation on the control command to generate a speed instruction by the EC chip; and
generating a pulse width modulation (PWM) signal to a fan, to prompt the fan to adjust its rotation speed according to the PWM signal.

9. The fan control method of claim 8, wherein the operating modes comprise an automatic mode, the processor generates the fan speed controlling signal according to the temperature from the temperature sensor, in response to the automatic mode.

10. The fan control method of claim 9, wherein the operation modes further comprises a manual mode, the processor outputs the fan speed controlling signal according to an input value from a user, in response to the manual mode.

11. The fan control method of claim 10, wherein the processor outputs the control command to the EC chip through a universal system bus (USB) cable.

12. The fan control method of claim 8, wherein the processor outputs the control command to the EC chip through a universal system bus (USB) cable.
